(19) United States
(12) Patent Application Publication
(10) Pub. No.: US 2014/0290722 A1
(43) Pub. Date: Oct. 2, 2014

(54) SOLAR MODULE

(71) Applicant: SANYO ELECTRIC CO., LTD., Osaka (JP)

(72) Inventors: Toshiyuki SAKUMA, Osaka (JP); Hitomi ICHINOSE, Osaka (JP); Tasuku ISHIGURO, Osaka (JP); Naoto IMADA, Osaka (JP)

(21) Appl. No.: 14/306,331

(22) Filed: Jun. 17, 2014

Related U.S. Application Data
(63) Continuation of application No. PCT/JP2012/082292, filed on Dec. 13, 2012.

(30) Foreign Application Priority Data
Dec. 22, 2011 (JP) 2011-281438
Dec. 22, 2011 (JP) 2011-281565
Mar. 6, 2012 (JP) 2012-048728

(51) Int. Cl. H01L 31/048

(52) U.S. Cl. CPC H01L 31/0481
USPC 136/251

(57) ABSTRACT

A solar module includes solar cells with first and second principal surfaces, a wiring member electrically connected to the first or second electrode of each of the solar cells, and a sealing member sealing the solar cells. The solar cells each includes first and second electrodes on the second principal surface. The sealing member includes a first sealing portion containing a non-crosslinking resin and located on a first principal surface side of the solar cells, and a second sealing portion containing a crosslinking resin and located on a second principal surface side of the solar cells.

### CROSS REFERENCE TO RELATED APPLICATIONS

This application is a continuation application of International Application No. PCT/JP2012/082292, filed on Dec. 13, 2012, entitled “SOLAR BATTERY MODULE”, which claims priority based on Article 8 of Patent Cooperation Treaty from prior Japanese Patent Applications No. 2011-281438, filed on Dec. 22, 2011, No. 2011-281565, filed on Dec. 22, 2011, and No. 2012-048728, filed on Mar. 06, 2012, the entire contents of which are incorporated herein by reference.

### BACKGROUND

The invention relates to a solar module.

As a solar module having improved photoelectric conversion efficiency, there has been known a solar module having back contact solar cells as described in Patent Document 1, for example.

Patent Document 1: Japanese Patent Application Publication No.2010-80887

### SUMMARY OF THE INVENTION

There is a demand for improvement of durability of a solar module.

One aspect of the invention provides a solar module having excellent durability.

A solar module of the embodiment includes solar cells, wiring members and a sealing member. The solar cells each include first and second principal surfaces. The solar cell includes first and second electrodes on the second principal surface. The wiring members are each connected to the first or second electrode of one of the solar cells. The sealing member seals the solar cells. The sealing member includes a first sealing portion and a second sealing portion. The first sealing portion contains a non-crosslinking resin. The first sealing portion is located on a first principal surface side of the solar cells. The second sealing portion contains a crosslinking resin. The second sealing portion is located on a second principal surface side of the solar cells.

The solar modules above have excellent durability.

### BRIEF DESCRIPTION OF THE DRAWINGS

FIG. 1 is a schematic cross sectional view of a solar module according to an embodiment.

FIG. 2 is a schematic plan view of a solar cell included in a solar module according to an embodiment.

FIG. 3 is a schematic cross sectional view of a portion of a solar module according to a first modified example.

FIG. 4 is a schematic cross sectional view of a portion of a solar module according to a second modified example.

### EMBODIMENTS

Hereinafter, embodiments of solar modules are described. Here, the embodiments are provided just for illustrative purposes. The invention is not limited at all to the following embodiments.

Moreover, the drawings referred in the embodiment are illustrated schematically, and the dimensional ratio and the like of objects drawn in the drawings are different from those of actual objects. The specific dimensional ratio and the like of objects should be determined with the following description taken into consideration.

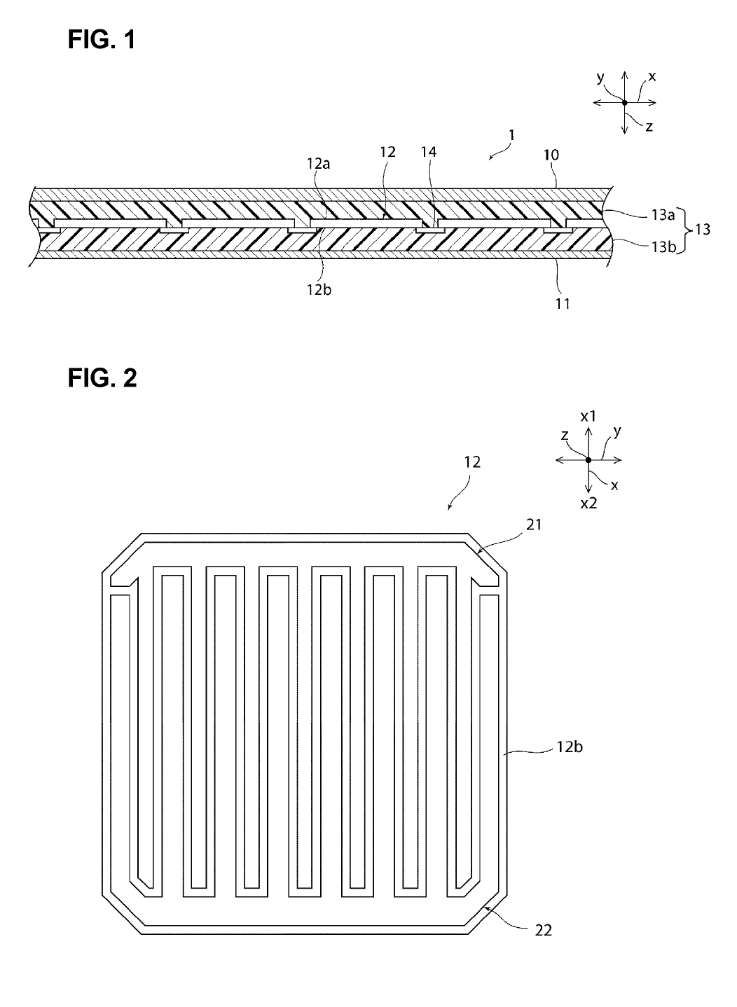

As illustrated in FIG. 1, solar module 1 includes solar cells 12. Each solar cell 12 includes first principal surface 12a and second principal surface 12b. A type of solar cell 12 is not particularly limited. For example, a crystalline silicon solar cell, a polycrystalline silicon solar cell or the like may be used as solar cell 12. Solar cell 12 may generate power only when receiving light at first principal surface 12a, or may generate power not only when receiving light at first principal surface 12a, but also when receiving light at second principal surface 12b.

Solar cell 12 is a back contact solar cell. As illustrated in FIG. 2, solar cell 12 includes first electrode 21 and second electrode 22 on second principal surface 12b. One of first electrode 21 and second electrode 22 is an electrode for collecting electrons, and the other one is an electrode for collecting holes. Although not illustrated, no electrode for collecting electrons or holes is provided on first principal surface 12a.

Solar cells 12 are electrically connected to each other by wiring members 14. More specifically, first electrode 21 in one of adjacent solar cells 12 is electrically connected to second electrode 22 in the other solar cell by wiring member 14. Thus, portions of one side of each wiring member 14 are electrically connected to second principal surfaces 12b of solar cells 12.

Note that wiring members 14 and solar cells 12 are bonded with a resin adhesive, solder or the like. It is preferable that wiring members 14 and solar cells 12 be bonded with a resin adhesive. The resin adhesive may contain a conducting material.

Sealing member 13 seals solar cells 12. Sealing member 13 has first sealing portion 13a and second sealing portion 13b. First sealing portion 13a is located on a first main surface 12a side of solar cells 12. First sealing portion 13a is also located between adjacent solar cells 12. Second sealing portion 13b is located on a second principal surface 12b side of solar cells 12.

First sealing portion 13a contains a non-crosslinking resin. The non-crosslinking resin preferably contains no vinyl acetate monomer, and is more preferably a polyolefin resin containing no vinyl acetate monomer. The polyolefin resins containing no vinyl acetate monomer preferably contains at least one of polyethylene resin and polypropylene resin.

In the embodiment, the non-crosslinking resin is a resin having a gel fraction of 50% or less. In the embodiment, the “gel fraction” is measured by the following measurement method. First, 1 g of a resin to be measured is prepared. Then, the resin is immersed in 100 ml of xylene for 24 hours at 120° C. Thereafter, residues in xylene are extracted and then dried at 80° C. for 16 hours. Subsequently, the mass of the dried residues is measured. From the result thus obtained, the gel fraction (%) is calculated based on the following equation (1) given below.

(Gel Fraction (%))=(Mass of Residues (g))/(Mass of Resin before Immersion (g)) (1).

Second sealing portion 13b contains a crosslinking resin. The crosslinking resin is preferably an ethylene-vinyl acetate copolymer (EVA). In the embodiment, the crosslinking resin is a resin having a gel fraction of more than 50%.

Second sealing portion 13b contains a colorant such as pigment. The color of the colorant is not particularly limited. The colorant may be white, for example. Specific examples of the white colorant include titanium dioxide, zinc oxide, white lead, barium sulfate, barium borate, calcium carbonate, magnesium oxide, and the like, for example.

Sealing member 13 is provided between first protection member 10 and second protection member 11. First protection member 10 is disposed on the first principal surface 12a side of solar cells 12. First protection member 10 can be made of a glass plate or the like, for example. Second protection member 11 is disposed on the second principal surface 12b side of solar cells 12. Second protection member 11 is opposed to first protection member 10. Second protection member 11 may be made of a resin, for example. Second protection member 11 may have a metal layer made of aluminum or the like.

In a general solar module, solar cells are sealed in a sealing member containing a crosslinking resin such as an ethylene-vinyl acetate copolymer (EVA). The crosslinking resin contains a crosslinking agent. The crosslinking agent contained in the sealing member may generate a gas inside the sealing member. If a gas is generated inside the sealing member, the solar cells and the sealing member may be detached from each other, which may deteriorate the durability of the solar module.

Instead, in the case where a whole sealing member is made of a non-crosslinking resin, for example, gas generation can be prevented from occurring inside the sealing member. However, the non-crosslinking resin becomes fluid at high temperature. For this reason, use of the sealing member entirely made of a non-crosslinking resin results in a situation where the solar cells and the wiring members cannot be firmly fixed to each other if the temperature of the solar module becomes high. As a result, the solar cells and the wiring members may be detached from each other, or the solar cells may be displaced.

In contrast, in solar module 1, sealing member 13 includes first sealing portion 13a and second sealing portion 13b. First sealing portion 13a contains the non-crosslinking resin. For this reason, gas generation due to a crosslinking agent rarely occurs in first sealing portion 13a, and solar cells 12 and first sealing portion 13a are rarely detached from each other. In addition, second sealing portion 13b contains the crosslinking resin. The stiffness of the crosslinking resin is higher than that of the non-crosslinking resin. Thus, even under high temperature, solar cells 12 and wiring members 14 can be firmly fixed in sealing member 13. Hence, solar module 1 is excellent in durability.

In the case of a back contact solar cell, solar cell 12 and wiring members 14 are detached from each other on second principal surface 12b. For this reason, the configuration in which second sealing portion 13b provided on the second principal surface 12b side is made of a crosslinking resin can make wiring members 14 unlikely to be detached from solar cells 12.

When the crosslinking resin contained in second sealing portion 13b is an ethylene-vinyl acetate copolymer, solar cells 12 can be more firmly fixed inside sealing member 13.

On the other hand, since no wiring member 14 is provided on the first principal surface 12a side, detachment of solar cells 12 and wiring members 14 does not occur on the first principal surface 12a side. For this reason, the configuration in which first sealing portion 13a provided on the first principal surface 12a side is made of a non-crosslinking resin can inhibit solar cells 12 and first sealing portion 13a from detachment from each other.

When the non-crosslinking resin contained in first sealing portion 13a contains no vinyl acetate monomer, gas generation due to the crosslinking agent more rarely occurs in first sealing portion 13a. Accordingly, solar cells 12 and first sealing portion 13a are more rarely detached from each other.

When solar cells 12 are sealed by first sealing portion 13a and second sealing portion 13b, wiring members 14 block the flowing of second sealing portion 13b, and first sealing portion 13a flows into spaces between adjacent solar cells 12. Containing the non-crosslinking resin, first sealing portion 13a becomes soft at high temperature. Thus, when the temperature of the solar module becomes high, sealing member 13 is unlikely to apply such stresses to solar cells 12 that adjacent solar cells 12 will move away from each other. Hence, solar cells 12 and first sealing portion 13a are more rarely detached from each other.

When second sealing portion 13b further contains a colorant, the optical reflectance of second sealing portion 13b can be enhanced. Thus, the light utilization efficiency can be improved. Moreover, since second sealing portion 13b contains the crosslinking resin and wiring members 14 block the flowing of second sealing portion 13b, second sealing portion 13b rarely flows even under high temperature. Consequently, second sealing portion 13b containing the colorant is effectively inhibited from reaching onto first principal surfaces 12a of solar cells 12.

Note that the colorant is preferably a while colorant made of titanium oxide or the like, for example.

(First Modified Example)

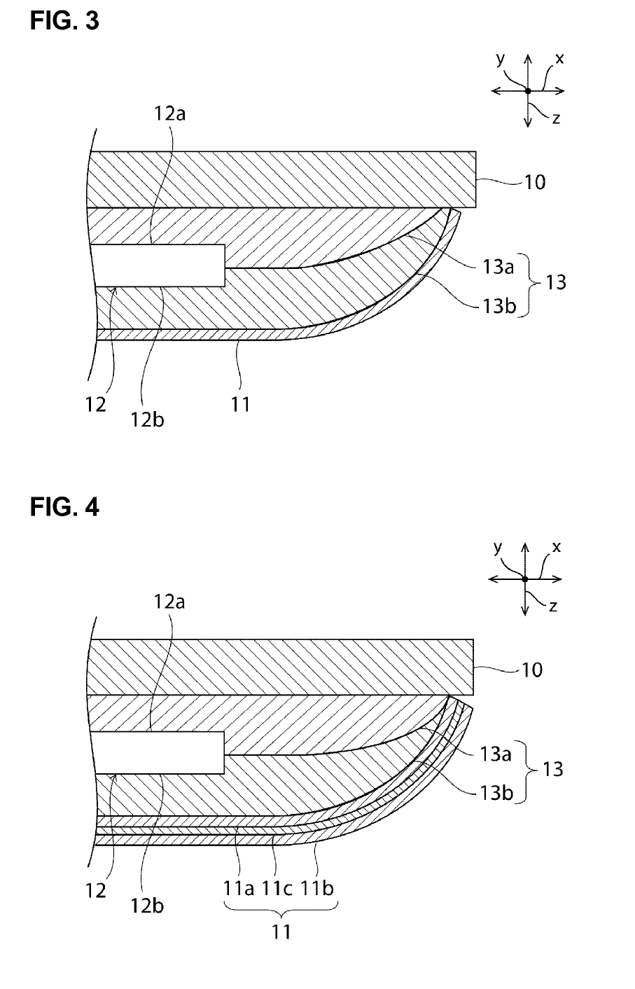

In a solar module according to a first modified example illustrated in FIG. 3, second sealing portion 13b containing pigment is provided to cover a surface and side surfaces of first sealing portion 13a. This configuration can inhibit light leakage from the side surfaces of the solar module. Thus, the utilization efficiency of light having entered the solar module can be further enhanced. Accordingly, more improved output properties can be obtained.

From the viewpoint of obtaining more improved output properties, it is preferable that end portions of second sealing portion 13b be in contact with first protection member 10. Moreover, it is preferable that second protection member 11 cover the surface and side surfaces of second sealing portion 13b.

Second sealing portion 13b preferably contains a crosslinking resin such as an ethylene-vinyl acetate copolymer. The crosslinking resin is low in fluidity even under high temperature. For this reason, if second sealing portion 13b contains a crosslinking resin, the fluidity of second sealing portion 13b is low even when the solar module has high temperature. This inhibits solar cells 12 or the like from displacement.

From the viewpoint of effectively inhibiting solar cells 12 or the like from displacement when the solar module has high temperature, it is preferable that the end portions of second sealing portion 13b containing the crosslinking resin be in contact with first protection member 10. This configuration is effective particularly when first sealing portion 13a contains a non-crosslinking resin such as polyethylene or polypropylene.

Note that, in terms of adhesion under high temperature, the non-crosslinking resin such as polyethylene or polypropylene is superior to the crosslinking resin such as an ethylene-vinyl acetate copolymer.

Thus, from the viewpoint of inhibiting detachment from solar cells 12 under high temperature, it is preferable that first sealing portion 13a contain a non-crosslinking resin and that second sealing portion 13b contain a crosslinking resin.

(Second Modified Example)

In a solar module according to a second modified example illustrated in FIG. 4, first sealing portion 13a located between first protection member 10 made of glass and solar cells 12 contains at least one of polyethylene and polypropylene. Here, polyethylene and polypropylene have a low water content. For this reason, when first sealing portion 13a contains at least one of polyethylene and polypropylene, the water content of first sealing portion 13a can be made low. Thus, an alkaline component such as Na contained in first protection member 10 rarely flows out into sealing member 13. Thus, the alkaline component such as Na contained in first protection member 10 can be effectively inhibited from reaching solar cells 12. This can inhibit deterioration of solar cells 12 due to the alkaline component. Consequently, the improved durability can be achieved.

Moreover, in the solar module, at least a surface layer of second protection member 11 on the first protection member 10 side contains at least one of polyethylene and polypropylene having a low water content. Thus, moisture is effectively inhibited from entering sealing member 13 through second protection member 11. In addition, second protection member 11 and an end portion of first sealing portion 13a containing at least one of polyethylene and polypropylene are in contact with each other. Thus, moisture is also effectively inhibited from entering sealing member 13 from side surfaces thereof. Hence, deterioration of solar cells 12 and wiring members 14 due to moisture is inhibited.

Further, at least the surface layer of second protection member 11 on the first protection member 10 side and first sealing portion 13a both contain at least one of polyethylene and polypropylene. Thus, resins contained in at least the surface layer of second protection member 11 on the first protection member 10 side and first sealing portion 13a can have solubility parameters between which the difference is 1 or less. As a result, the end portion of second protection member 11 and the end portion of first sealing portion 13a can achieve high adhesion, so that second protection member 11 and first sealing portion 13a are effectively inhibited from detachment from each other.

Note that, in the present modified example, second protection member 11 includes first portion 11a forming the surface layer on the first protection member 10 side, second portion 11b forming a surface layer on the opposite side from first protection member 10, and third portion 11c provided between first portion 11a and second portion 11b. First portion 11a and third portion 11c each contain at least one of polyethylene and polypropylene. Second portion 11b is made of an aluminum foil or the like, for example.

The invention includes other embodiments in addition to the above-described embodiments without departing from the spirit of the invention. The embodiments are to be considered in all respects as illustrative, and not restrictive. The scope of the invention is indicated by the appended claims rather than by the foregoing description. Hence, all configurations including the meaning and range within equivalent arrangements of the claims are intended to be embraced in the invention.

1. A solar module comprising:
solar cells with first and second principal surfaces, the solar cells each including first and second electrodes on the second principal surface;
a wiring member electrically connected to the first or second electrode of each of the solar cells; and
a sealing member sealing the solar cells, wherein the sealing member includes:
a first sealing portion containing a non-crosslinking resin and located on a first principal surface side of the solar cells, and
a second sealing portion containing a crosslinking resin and located on a second principal surface side of the solar cells.

2. The solar module according to claim 1, wherein
the non-crosslinking resin contains no vinyl acetate monomer.

3. The solar module according to claim 1, wherein
the crosslinking resin is an ethylene-vinyl acetate copolymer.

4. The solar module according to claim 1, wherein
the second sealing portion further contains a colorant.

5. The solar module according to claim 1, comprising two or more of the solar cells, wherein
in the sealing member, the first sealing portion forms a portion between each adjacent two of the solar cells.

6. The solar module according to claim 1, wherein
the second sealing portion contains pigment to improve an optical reflectance of the second sealing portion, and is provided to cover a surface and side surfaces of the first sealing portion.

7. The solar module according to claim 6, further comprising:
a first protection member provided on the first sealing portion; and
a second protection member provided on the second sealing portion, wherein
the second sealing portion is in contact with the first protection member.

8. The solar module according to claim 1, further comprising:
a first protection member provided on the first sealing portion and made of glass; and
a second protection member provided on the second sealing portion, wherein
the first sealing portion contains at least one of polyethylene and polypropylene, and
an end part of the first sealing portion extends outward beyond an end part of the second sealing portion, and is in contact with the second protection member.

9. The solar module according to claim 8, wherein
a surface layer of the second protection member on a first protection member side contains a resin whose solubility parameter has a different of 1 or less from a solubility parameter of the at least one of polyethylene and polypropylene contained in the first sealing portion.

10. The solar module according to claim 9, wherein
the surface layer of the second protection member on the first protection member side contains at least one of polyethylene and polypropylene.
